(19) United States
(12) Patent Application Publication
(10) Pub. No.: US 2011/0018643 A1
(43) Pub. Date: Jan. 27, 2011

(54) VOLTAGE CONTROLLED OSCILLATOR WITH MICROSTRIP LINE SUITABLE FOR COARSE ADJUSTMENT OF OSCILLATION FREQUENCY BAND

(76) Inventor: Yoshiaki Yamaki, Niigata-ken (JP)

Correspondence Address: BRINKS HOFER GILSON & LIONE, P.O. BOX 10395, CHICAGO, IL, 60610, US

(21) Appl. No.: 12/841,564

(22) Filed: Jul. 22, 2010

(30) Foreign Application Priority Data
Jul. 24, 2009 (JP) 2009-172988

(51) Int. Cl. H03B 5/24

(52) U.S. Cl. 331/108 R

(57) ABSTRACT

A voltage controlled oscillator with a microstrip line suitable for coarse adjustment of an oscillation frequency band, the voltage controlled oscillator includes a transistor for oscillation that outputs an oscillation signal; a microstrip line formed on a substrate together with the transistor for oscillation, having one end connected to the transistor for oscillation and the other end connected to a ground electrode formed on the substrate, and thus constituting a part of a frequency determining element that determines a frequency of the oscillation signal according to a line length from the one end of the microstrip line to the ground electrode; and a conductor for coarse adjustment that connects between the one end and the other end of the microstrip line to the ground electrode, thereby reducing the line length of the microstrip line in the connection state.

### CROSS REFERENCE TO RELATED APPLICATION

The present invention contains subject matter related to and claims priority to Japanese Patent Application JP 2009-172988 filed in the Japanese Patent Office on Jul. 24, 2009, the entire content of which is incorporated herein by reference.

### BACKGROUND

1. Technical Field

The present disclosure relates to an oscillator with a microstrip line suitable for coarse adjustment of an oscillation frequency band.

2. Related Art

In regard to such oscillators, there is known a technology of performing coarse adjustment of an oscillation frequency band by partially trimming a microstrip line formed on the upper surface of a substrate (for example, refer to the third page and FIGS. 2 and 3 of Japanese Unexamined Patent Application Publication No. 2001-94346). According to the existing technology, first and second resonant circuits are formed on the upper surface of the substrate while being connected in parallel to each other, and have first and second microstrip lines, respectively. The first and second microstrip lines are arranged in parallel to each other on the upper surface of the substrate, and one end of the first microstrip line is connected to one end of the second microstrip line through a third microstrip line. Further, the substrate is formed with a plurality of through holes at positions thereof corresponding to the third microstrip line, and ground conductors located at the lower surface of the substrate are connected to the third microstrip line through the through holes.

According to the existing technology, since a part of the plurality of through holes is sequentially subject to trimming (e.g., cutting using a drilling process) from the through holes located adjacent to the first microstrip line, a part of the third microstrip line is added to the first microstrip line, so that a line length up to a ground point is changed, resulting in a step-by-step change in an inductance value. Since the position of each through hole is determined in advance, when the holes are sequentially subject to trimming to some extent, the degree of coarse adjustment of an oscillation frequency can be understood in advance. Thus, according to the existing technology, coarse adjustment of the oscillation frequency can be quickly and easily performed according

However, when the oscillation frequency is adjusted as described in the existing technology, if the through holes are cut together with the microstrip line, the line width of the microstrip line is thus narrowed, resulting in the deterioration of a Q factor. In general, since Q characteristics are easily affected by a part with the narrowest width on the microstrip line, when the width of the microstrip line is extremely narrowed by trimming as described in the existing technology, the deterioration of the Q factor may easily occur due to frequency adjustment and exchange. to the number of the through holes to be trimmed.

### SUMMARY

An oscillator includes a transistor for oscillation that outputs an oscillation signal; a microstrip line formed on a substrate together with the transistor for oscillation, having one end connected to the transistor for oscillation and the other end connected to a ground electrode formed on the substrate, and thus constituting a part of a frequency determining element that determines a frequency of the oscillation signal according to aline length from the one end of the microstrip line to the ground electrode; and a conductor for coarse adjustment that connects between the one end and the other end of the microstrip line to the ground electrode, thereby reducing the line length of the microstrip line in the connection state.

According to the oscillator of the present invention, with respect to the microstrip line constituting a part of the element that determines an oscillation frequency, it is possible to perform adjustment of the oscillation frequency by using a conductor for coarse adjustment provided separately from the microstrip line. That is, the conductor for coarse adjustment connects between the one end and the other end of the microstrip line to the ground electrode on the substrate, and in such a state, the line length from the one end of the microstrip line to the ground electrode is reduced. Consequently, in the state in which the conductor for coarse adjustment is arranged (maintained) on the substrate, the frequency of the oscillation signal is determined based on the reduced line length (inductance is small). In such a case, the frequency band of the oscillation signal due to the transistor for oscillation is set to a relatively high value.

Meanwhile, in the state in which the conductor for coarse adjustment is removed from the substrate, the line length of the microstrip line becomes the original length of the entire range from the one end to the other end (ground electrode) thereof. In such a case, since the frequency band of the oscillation signal is determined based on the original line length (inductance is large) of the microstrip line, the frequency band of the oscillation signal due to the transistor for oscillation is set to a relatively low value.

According to the present invention as described above, since the oscillation frequency of the oscillator can be significantly changed by removing the conductor for coarse adjustment provided separately from the microstrip line from the substrate, it is possible to cope with a plurality of frequency bands on a substrate with the same configuration (the pattern of the microstrip line). In addition, since no change occurs in the line width of the microstrip line before and after the conductor for coarse adjustment is removed, deterioration of a Q factor does not occur due to the adjustment of the frequency band.

### BRIEF DESCRIPTION OF THE DRAWINGS

FIG. 1 is a circuit diagram schematically illustrating the configuration of a voltage controlled oscillator according to a first embodiment.

FIGS. 2A and 2B are detailed plan views illustrating the configuration of a microstrip line applied to a voltage controlled oscillator according to a first embodiment.

FIGS. 3A and 3B are plan views illustrating a microstrip line in which a conductor for coarse adjustment is removed (after trimming).

FIGS. 4A and 4B are plan views illustrating a configuration example of a microstrip line applied to a voltage controlled oscillator of a second embodiment.

FIGS. 5A and 5B are plan views illustrating microstrip line in which one conductor for coarse adjustment is removed (after trimming of a first step).

FIGS. 6A and 6B are plan views illustrating a microstrip line in which the other conductor for coarse adjustment is removed (after trimming of a second step).

FIGS. 7A and 4B are plan views illustrating a configuration example of a microstrip line applied to a voltage controlled oscillator of a third embodiment.

FIGS. 8A and 8B are diagrams illustrating an example of trimming a conductor for coarse adjustment in a microstrip line.

### DESCRIPTION OF EXEMPLARY EMBODIMENTS

Hereinafter, embodiments of the invention will be described with reference to the accompanying drawings. In the following description, an embodiment of a Voltage Controlled Oscillator (VCO) that voltage-controls an oscillation frequency by using a varactor diode is exemplified. However, the invention is not limited to the configuration of the voltage controlled oscillator.

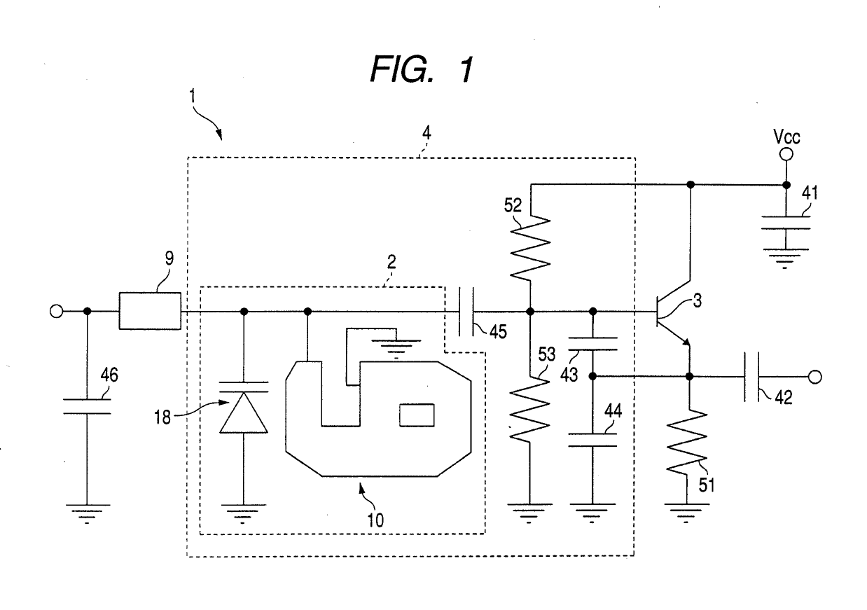

FIG. 1 is a circuit diagram schematically illustrating the configuration of the voltage controlled oscillator 1 according to a first embodiment. The voltage controlled oscillator 1, for example, includes wiring patterns (not shown) formed on the upper surface of a substrate, and various circuit elements (transistors, resistors, capacitors and the like) mounted on the substrate. Further, although not shown in FIG. 1, a metal cover is provided on the substrate to cover the whole of the circuit. Hereinafter, the circuit configuration of the voltage controlled oscillator 1 will be described.

The voltage controlled oscillator 1 mainly includes a transistor 3 for oscillation and a tank circuit 4. Further, the tank circuit 4 includes two feedback capacitors 43 and 44, vias resistors 52 and 53 and a resonant circuit 2. Such a voltage controlled oscillator 1 basically includes a Colpitts oscillator circuit in which a base of the transistor 3 for oscillation is connected to one end of a resonant circuit 2 through a coupling capacitor 45.

That is, a collector of the transistor 3 for oscillation is connected to the supply voltage Vcc and is grounded in a high frequency manner through a bypass capacitor 4. Further, an emitter of the transistor 3 for oscillation is grounded through an emitter vias resistor 51. In addition, a vias voltage is applied to the base of the transistor 3 for oscillation from a connection point between the two base vias resistors 52 and 53 serially connected to each other.

The feedback capacitor 43 of the two feedback capacitors 43 and 44 in the tank circuit 4 connects between the emitter and the base of the transistor 3 for oscillation. Further, the feedback capacitor 44 is connected between the collector (a connected state) and the emitter of the transistor 3 for oscillation on the circuit. In addition, the coupling capacitor 45 connected between the base of the transistor 3 for oscillation and the resonant circuit 2 adjusts impedance of the tank circuit 4.

The resonant circuit 2 includes a varactor diode 18 and a microstrip line 10. The resonant circuit 2 receives a control voltage from a control terminal through a choke inductor 9. In the resonant circuit 2, a cathode of the varactor diode 18 is connected in parallel to one end of the microstrip line 10. Further, an anode of the varactor diode 18 and the other end of the microstrip line 10 are grounded, respectively. The control terminal is grounded in a high frequency manner through a separate bypass capacitor 46.

If the control voltage is applied to the resonant circuit 2 through the control terminal, the capacitance of the varactor diode 18 is changed, resulting in a change in the resonant frequency of the resonant circuit 2. Consequently, it is possible to control the oscillation frequency of the entire voltage controlled oscillator 1 by using the control voltage. At this time, the resonant frequency of the resonant circuit 2 is determined according to the inductance of the microstrip line 10 in addition to the capacitance of the varactor diode 18. Therefore, the oscillation frequency of the voltage controlled oscillator 1 can be adjusted (coarsely adjusted) by changing the inductance (mainly, a line length) of the microstrip line 10 through trimming.

The voltage controlled oscillator 1 according to the first embodiment includes the microstrip line 10 suitable for coarse adjustment of the oscillation frequency as described above, and particularly, the microstrip line 10 can significantly change the oscillation frequency band of the voltage controlled oscillator 1 before and after the trimming thereof.

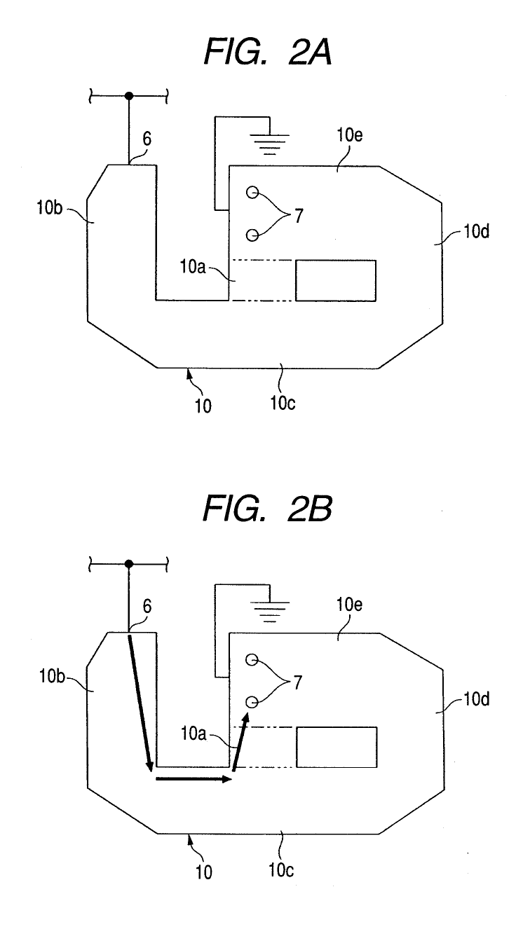

FIGS. 2A and 2B are detailed plan views illustrating the configuration of the microstrip line 10 applied to the voltage controlled oscillator 1 according to the first embodiment.

[Configuration Before Trimming]

Referring to FIG. 2A, as described above, one end of the microstrip line 10 is connected to the control terminal (not shown in FIG. 2A) and the other end of the microstrip line 10 is grounded on the circuit. On the substrate (not shown), for example, a plurality of vias 7 are formed at the other end position of the microstrip line 10, and the other end of the microstrip line 10 is connected to a ground electrode (not shown) through the vias 7. Further, the ground electrode, for example, is formed on the lower surface of the substrate (not shown).

The microstrip line 10 is provided at one end thereof with a signal input terminal 6, and a line from the signal input terminal 6 to the other end (ground) is formed in a spiral shape. In such an example, the one end of the microstrip line 10 is located at an outer side of the spiral, and the other end of the microstrip line 10 is located at the central side thereof. In more detail, in the microstrip line 10, if a portion of one end located at the outer side of the spiral is employed as an input conductive portion 10b and a portion of the other end further located at the central side of the spiral is employed as a ground conductive portion 10e, a configuration is obtained in which two intermediate conductive portions 10c and 10d are interposed between the conductive portions 10b and 10e. These four conductive portions 10b to 10e are sequentially connected in series to each other from the one end (the signal input terminal 6) to the other end of the microstrip line 10.

Among the conductive portions, the input conductive portion 10b and the first intermediate conductive portion 10c are arranged approximately at a right angle to each other on the substrate, and the intermediate conductive portion 10c and the second intermediate conductive portion 10d are arranged approximately at a right angle to each other on the substrate. In addition, the second intermediate conductive portion 10d and the ground conductive portion 10e are arranged approximately at a right angle to each other on the substrate. As described above, these four conductive portions 10b to 10e are sequentially connected in series to each other in the state in which the conductive portions 10b and 10c, the conductive portions 10c and 10d and the conductive portions 10d and 10e are sequentially arranged approximately at a right angle to each other, so that the microstrip line 10 has a rectangular spiral shape as a whole.

All the conductive portions 10b to 10e constitute the line (conductive line) from the one end to the other end of the microstrip line 10. In addition, a conductor 10a for coarse adjustment is connected to the microstrip line 10. The conductor 10a for coarse adjustment is formed on the substrate as a conductive pattern similarly to the other conductive portions 10b to 10e. Particularly, in the first embodiment, the conductor 10a for coarse adjustment is arranged to serve as a bridge between the ground, conductive portion 10e and the intermediate conductive portion 10c. Thus, the intermediate conductive portion 10c located between the one end and the other end of the microstrip line 10 is connected to the ground electrode through the conductor 10a for coarse adjustment. In such an example, the conductor 10a for coarse adjustment is added to the four conductive portions 10b to 10e, so that the entire microstrip line 10 has a shape like a figure “6”.

[Line Length Before Trimming]

Referring to FIG. 2B, if a control voltage is input (applied) to the resonant circuit 2 in the state (before trimming) in which the conductor 10a for coarse adjustment is maintained on the substrate, as indicated by the arrow in FIG. 2B, the shortest range from the signal input terminal 6 to the via 7 by way of the input conductive portion 10b, a part of an upstream side of the intermediate conductive portion 10c when seen in the conduction direction, and the conductor 10a for coarse adjustment in the middle of the intermediate conductive portion 10c becomes a conductive line as the microstrip line 10. In such a case, since the range from a part of the intermediate conductive portion 10c, which is located at a downstream side as compared with the conductor 10a for coarse adjustment when seen in the conduction direction, to the ground conductive portion 10e in front of the via 7 by way of the next intermediate conductive portion 10d does not substantially contribute to conduction, the line length of the microstrip line 10 is reduced to that extent.

In the state in which the conductor 10a for coarse adjustment is maintained as described above, the inductance of the microstrip line 10 is determined after the line length of the microstrip line 10 is reduced (shorter than the original entire length from the one end to the other end thereof). In the first embodiment, the resonant frequency (oscillation frequency of the voltage controlled oscillator 1) of the resonant circuit 2 at that time, for example, can be adjusted to a 2 GHz band.

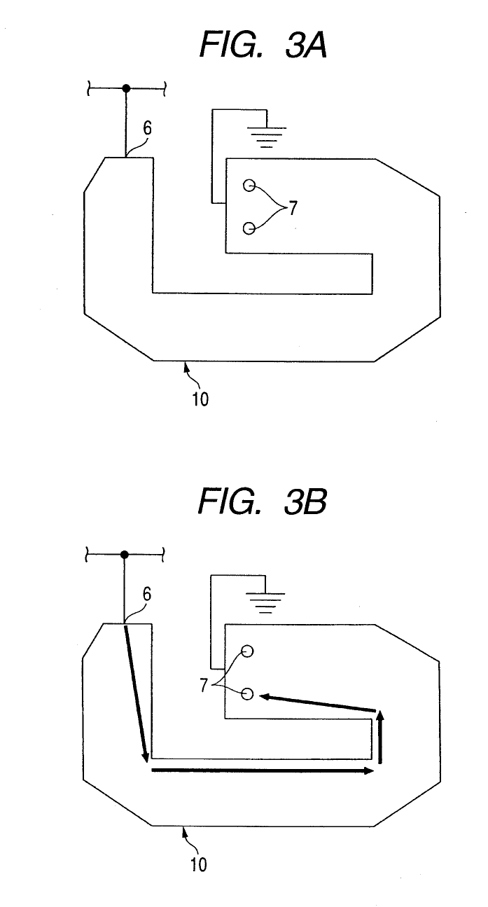

Next, FIGS. 3A and 3B are plan views illustrating the microstrip line 10 after removing the conductor 10a for coarse adjustment (after trimming). The conductor 10a for coarse adjustment, for example, can be easily removed from the substrate by using automatic machine (drilling machine, a laser irradiator and the like).

[After Trimming]

Referring to FIG. 3A, if the conductor 10a for coarse adjustment is removed from the substrate by trimming, the microstrip line 10 includes only the input conductive portion 10b, the first intermediate conductive portion 10c, the second intermediate conductive portion 10d and the ground conductive portion 10e, starting from the signal input terminal 6.

[Line Length after Trimming]

Referring to FIG. 3B, if a control voltage is input (applied) to the resonant circuit 2 after the trimming, as indicated by the arrow in FIG. 3B, the range from the signal input terminal 6 to the via 7 by way of the input conductive portion 10b, the first intermediate conductive portion 10c, the second intermediate conductive portion 10d and the ground conductive portion 10e becomes a conductive line as the microstrip line 10. In such a case, since the range including the whole of the first intermediate conductive portion 10c, the next intermediate conductive portion 10d, and the ground conductive portion 10e in front of the via 7 contributes to the conduction, the line length of the microstrip line 10 extends to that extent as compared with the case in which the trimming is not performed.

In the state in which the conductor 10a for coarse adjustment has been removed as described above, the inductance of the microstrip line 10 is determined after the line length of the microstrip line 10 extends (the original entire length) as compared with the case in which the trimming is not performed. In addition, in the first embodiment, the resonant frequency (oscillation frequency of the voltage controlled oscillator 1) of the resonant circuit 2 at that time, for example, can be adjusted to a 1.5 GHz band.

In the microstrip line 10 as described above, the conductor 10a for coarse adjustment is formed in advance at a place where the intermediate conductive portion 10c located between the one end (the signal input terminal 6) and the other end of the microstrip line 10 is connected (short-circuited) to the ground electrode, so that the line length as a whole can be reduced before the trimming, as compared with the original length. Consequently, the oscillation frequency band of the voltage controlled oscillator 1 can be set to a relatively high value (e.g., a 2 GHz band) in the state in which the trimming is not performed. Meanwhile, if the conductor 10a for coarse adjustment is removed by the trimming, the entire line length of the microstrip line 10 increases (becomes the original length) as compared with the case in which the trimming is not performed, so that coarse adjustment to a low oscillation frequency band can be easily performed as compared with the case in which the trimming is not performed.

In addition, the line width of the microstrip line 10 is not narrowed even after the trimming is performed as shown in FIGS. 3A and 3B, so that extreme deterioration of the Q factor can be prevented even if the oscillation frequency is coarsely adjusted by the trimming.

### Second Embodiment

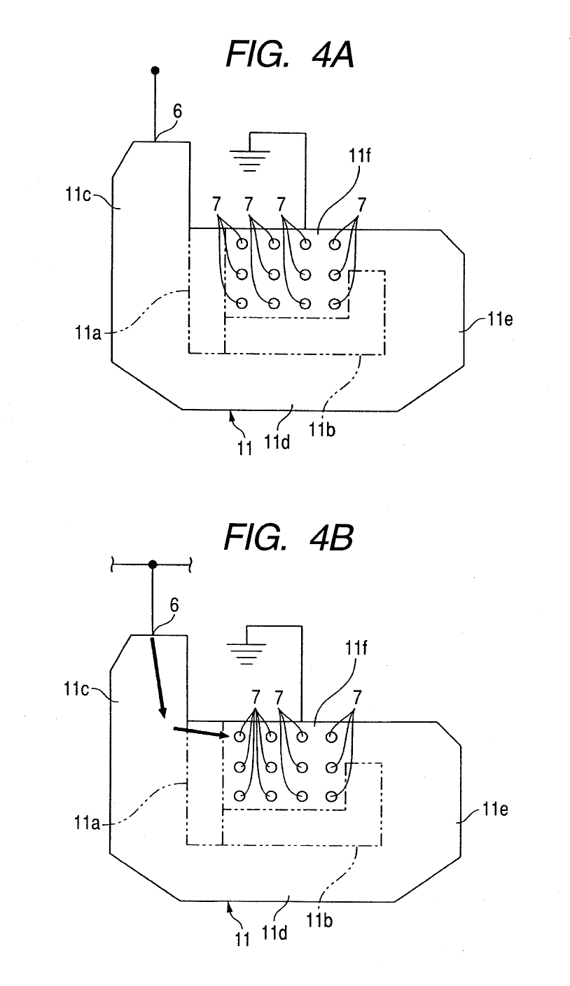

Next, the voltage controlled oscillator 1 of the second embodiment will be described. FIGS. 4A and 4B are plan views illustrating a configuration example of a microstrip line 11 applied to the voltage controlled oscillator 1 of the second embodiment. In addition, the voltage controlled oscillator 1 of the second embodiment has the same circuit configuration as that of the first embodiment, except for the microstrip line 11 with a configuration different from that of the first embodiment. Hereinafter, the microstrip line 11 applied to the second embodiment will be described.

[Configuration Before Trimming]

Referring to FIG. 4A, one end of the microstrip line 11 used for the second embodiment is also connected to the control terminal (not shown in FIG. 4A) and the other end of the microstrip line 11 is connected to the ground electrode on the circuit. As indicated by a two-dot chain line in FIG. 4A, the microstrip line 11 has a configuration in which two conductors 11a and 11b for coarse adjustment are integrally formed with each other in an internal area thereof.

That is, the microstrip line 11 is provided at one end thereof with an input conductive portion 11c and at the other end thereof with a ground conductive portion 11f. Between them, the input conductive portion 11c is continuous to the signal input terminal 6, and the ground conductive portion 11f is connected to the ground electrode (not shown) through a plurality of vias 7. Further, two intermediate conductive portions 11d and 11e are arranged between the input conductive portion 11c and the ground conductive portion 11f. However, before trimming is performed, the conductor 11a for coarse adjustment is interposed between the input conductive portion 11c and the ground conductive portion 11f while being integrally formed with them, and the other conductor 11b for coarse adjustment is interposed between the two intermediate conductive portions 11d and 11e and the ground conductive portion 11f while being integrally formed with them. For this reason, it appears that the input conductive portion 11c and the ground conductive portion 11f, and further the intermediate conductive portions 11d and 11e and the ground conductive portion 11f are continuously formed as the same conductive patterns.

Hereinafter, the microstrip line 11 will be described while focusing on each portion thereof. First, the input conductive portion 11c is arranged approximately perpendicular to the first intermediate conductive portion 11d, and the first intermediate conductive portion 11d is arranged approximately perpendicular to the second intermediate conductive portion 11e. The ground conductive portion 11f extends approximately at a right angle toward the input conductive portion 11c from a terminal end of the second intermediate conductive portion 11e, and is spread to a rectangular shape with a certain size from there. In an area spreading to the rectangular shape of the ground conductive portion 11f, the plurality (herein, 12) of vias 7 are arranged in a matrix shape. When the input conductive portion 11c, the intermediate conductive portions 11d and 11e, and the ground conductive portion 11f are seen in a continuous manner, it can be understood that the line from one end (the signal input terminal 6) to the other end (ground) of the microstrip line 11 is formed in a spiral shape.

Further, the two conductors 11a and 11b for coarse adjustment are serially arranged to surround the ground conductive portion 11f in the microstrip line 11. Between them, the conductor 11a for coarse adjustment is arranged at an inner side of the spiral along the input conductive portion 11c and has an external appearance with a strip shape as indicated by a two-dot chain line in FIG. 4A. At this position, the conductor 11a for coarse adjustment employs the outer side of the spiral as a starting end and extends in parallel to the input conductive portion 11c, and a terminal end of the conductor 11a for coarse adjustment reaches a connection point between the input conductive portion 11c and the first intermediate conductive portion 11d. The other intermediate conductor 11b for coarse adjustment is arranged inside the spiral along the two intermediate conductive portions 11d and 11e, and has an external appearance with a substantially L shape (key shape) as indicated by a two-dot chain line in FIG. 4A. At this position, the conductor 11b for coarse adjustment employs the connection point between the input conductive portion 11c and the first intermediate conductive portion 11d as a starting end and extends in the spiral direction, and a terminal end of the conductor 11b for coarse adjustment reaches a connection point between the second intermediate conductive portion lie and the ground conductive portion 11f.

[Line Length Before Trimming]

Referring to FIG. 4B, if a control voltage is input (applied) to the resonant circuit 2 in the state (before trimming) in which the two conductors 11a and 11b for coarse adjustment are maintained on the substrate, as indicated by the arrow in FIG. 4B, the shortest range from the signal input terminal 6 to the via 7 by way of a part of an upstream side of the input conductive portion 11c when seen in the conduction direction, and the conductor 11a for coarse adjustment becomes a conductive line as the microstrip line 11. In such a case, since the range from a part of the input conductive portion 11c, which is adjacent to the conductor 11a for coarse adjustment when seen in the width direction, to the intermediate conductive portions 11d and 11e (including the other conductor 11b for coarse adjustment) after the part does not substantially contribute to conduction, the line length of the microstrip line 11 is minimized in such a state.

In the state in which the two conductors 11a and 11b for coarse adjustment are maintained as described above, the inductance of the microstrip line 11 is determined after the line length of the microstrip line 11 is minimized. In the second embodiment, the resonant frequency (oscillation frequency of the voltage controlled oscillator 1) of the resonant circuit 2 at that time, for example, can be adjusted to a 2 GHz band.

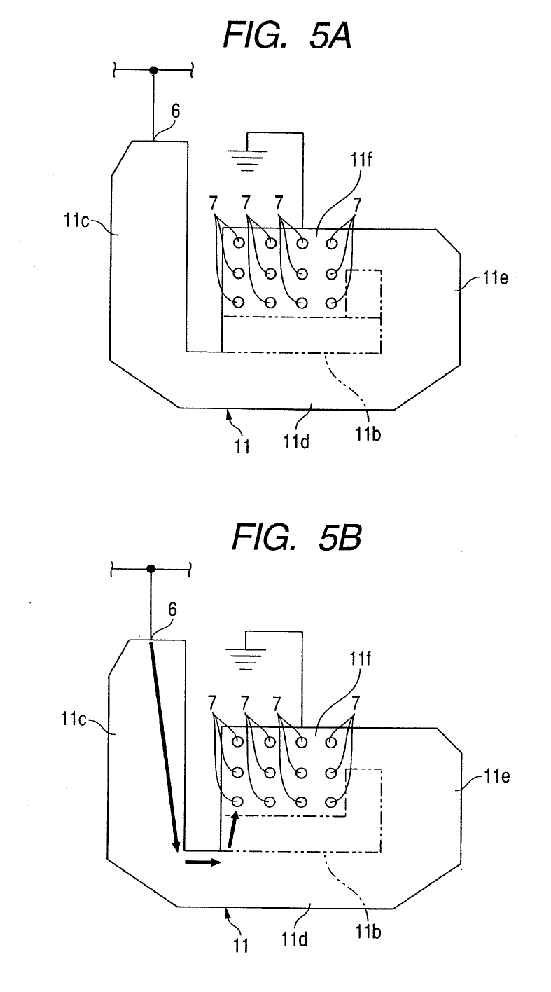

Next, FIGS. 5A and 5B are plan views illustrating the microstrip line 11 after removing the conductor 11a for coarse adjustment of the two conductors (after trimming of a first step). In the second embodiment, the conductor 11a for coarse adjustment can be easily removed from the substrate by using automatic machine similarly to the first embodiment.

[After Trimming of First Step]

Referring to FIG. 5A, the trimming of the first step is performed with respect to the microstrip line 11, so that the input conductive portion 11c is separated from the ground conductive portion 11f on the substrate. In addition, the other conductor 11b for coarse adjustment remains on the substrate.

[Line Length After Trimming of First Step]

Referring to FIG. 5B, if a control voltage is input (applied) to the resonant circuit 2 after the trimming of the first step, as indicated by the arrow in FIG. 5B, the shortest range from the signal input terminal 6 to the vias 7 by way of the whole of the input conductive portion 11c, a part of the first intermediate conductive portion 11d, and the remaining conductor 11b for coarse adjustment becomes a conductive line as the microstrip line 11. In such a case, since the whole of the input conductive portion 11c contributes to the conduction differently from the case in which the trimming is not performed, the range from the part of the first intermediate conductive portion 11d and the remaining conductor 11b for coarse adjustment to the front of the vias 7 of the ground conductive portion 11f contributes to the conduction. Consequently, in such a case, the line length of the microstrip line 11 extends by one step as compared with the case in which the trimming is not performed.

In the state in which the conductor 11a for coarse adjustment is removed by the trimming of the first step as described above, the inductance of the microstrip line 11 is determined after the line length of the microstrip line 11 extends by one step as compared with the case in which the trimming is not performed. In the second embodiment, the resonant frequency (oscillation frequency of the voltage controlled oscillator 1) of the resonant circuit 2 at that time, for example, can be adjusted to a 1.5 GHz band.

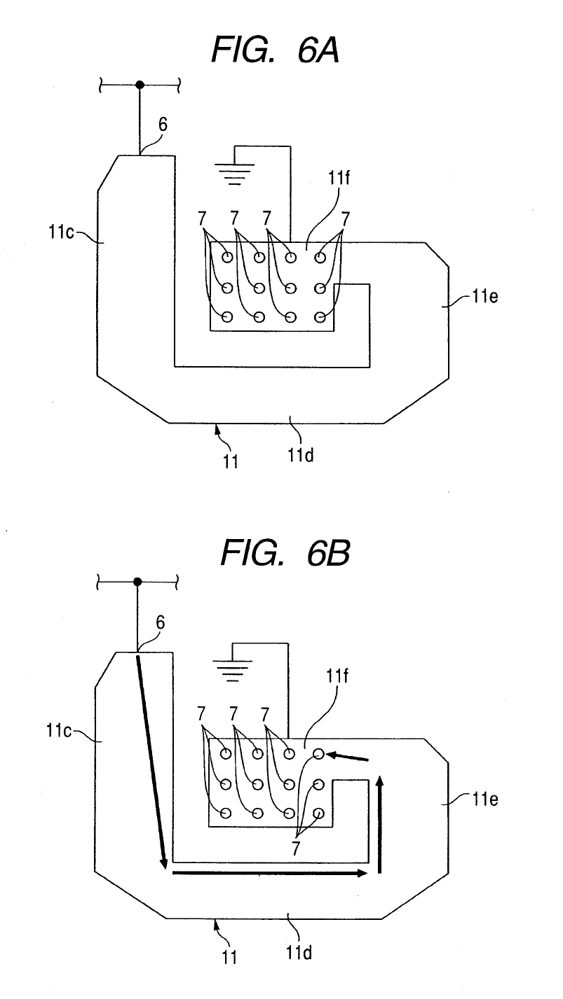

FIGS. 6A and 6B are plan views illustrating the microstrip line 11 after removing the other conductor 11b for coarse adjustment (after trimming of a second step). In the second embodiment, the conductor 11b for coarse adjustment can be easily removed from the substrate by using automatic machine similarly to the above.

[After Trimming of Second Step]

Referring to FIG. 6A, the trimming of the second step is performed with respect to the microstrip line 11, so that the intermediate conductive portion 11d is separated from the ground conductive portion 11f on the substrate in addition to the trimming of the first step. Therefore, it is apparent that the microstrip line 11 has a spiral shape as a whole.

[Line Length After Trimming of Second Step]

Referring to FIG. 6B, if a control voltage is input (applied) to the resonant circuit 2 after the trimming of the second step, as indicated by the arrow in FIG. 6B, the range from the signal input terminal 6 to the vias 7 by way of the whole of the input conductive portion 11c, the whole of the first intermediate conductive portion 11d, the whole of the second intermediate conductive portion 11e, and the ground conductive portion 11f becomes a conductive line as the microstrip line 11. In such a case, since the entire range from one end to the other end of the microstrip line 11 contributes to the conduction differently from the cases in which the trimming is not performed and the trimming of the first step is performed, the line length of the microstrip line 11 is maximized.

In the state in which the other conductor 11b for coarse adjustment is removed by the trimming of the second step as described above, the inductance of the microstrip line 11 is determined after the line length of the microstrip line 11 is maximized. In the second embodiment, the resonant frequency (oscillation frequency of the voltage controlled oscillator 1) of the resonant circuit 2 at that time, for example, can be adjusted to a 1 GHz band.

In the microstrip line 11 applied to the voltage controlled oscillator 1 according to the second embodiment, since the conductor 11a for coarse adjustment is formed in advance at a place where the input conductive portion 11c located between the one end (the signal input terminal 6) and the other end (vias 7) of the microstrip line 11 is connected (short-circuited) to the ground electrode, and the other conductor 11b for coarse adjustment is formed in advance at a place where the intermediate conductive portions 11d and 11e are connected (short-circuited) to the ground electrode, for example, the following coarse adjustment is possible.

(1) That is, before the trimming is performed with respect to the microstrip line 11, the line length as a whole can be minimized, and in such a state, the oscillation frequency band of the voltage controlled oscillator 1 can be set to a relatively high value (e.g., a 2 GHz band).
(2) Next, if the conductor 11a for coarse adjustment is removed by the trimming of the first step, the line length of the microstrip line 11 as a whole increases by one step as compared with the case in which the trimming is not performed, so that coarse adjustment to a low oscillation frequency band by one step can be easily performed as compared with the case in which the trimming is not performed.
(3) In addition, if the other conductor 11b for coarse adjustment is removed by the trimming of the second step, the line length of the microstrip line 11 as a whole is maximized, so that coarse adjustment to the lowest oscillation frequency band can be easily performed.

Moreover, in the second embodiment, the line width (minimum width) of the microstrip line 11 is not narrowed after the trimming of both the first step and the second step. Consequently, even in the second embodiment, extreme deterioration of the Q factor can be prevented even if the oscillation frequency band is coarsely adjusted by trimming the microstrip line 11.

[Modification of Second Embodiment]

In addition, in the second embodiment, the conductors for coarse adjustment are divided into two conductors 11a and 11b and are subject to the trimming. However, the conductors 11a and 11b for coarse adjustment can be treated as a continuous semiconductor area for coarse adjustment. In such a case, the conductors (reference numerals 11a and 11b) for coarse adjustment have a certain length as a whole, a part of the conductors is removed by the trimming step by step, and the length of a remaining area is continuously reduced, so that coarse adjustment of an oscillation frequency band can be continuously performed.

In this regard, for example, in a conventional general coarse adjustment, when an oscillation frequency band is significantly changed, there exists a technique for changing a conductive pattern of a microstrip line. In such a case, since a difference exists in an area (size, surface edge) of a substrate, which is occupied by the conductive pattern of the microstrip'line, for each oscillation frequency band, it is necessary to change a substrate layout according to the change in the conductive pattern of the microstrip line. However, when employing the first and second embodiments, no change occurs in the maximum area of the substrate, which is occupied by the microstrip lines 10 and 11 before and after the coarse adjustment. Consequently, even if the conductive patterns of the microstrip lines 10 and 11 are equal to each other on the same substrate, it is possible to easily realize coarse adjustment corresponding to various oscillation frequency bands.

### Third Embodiment

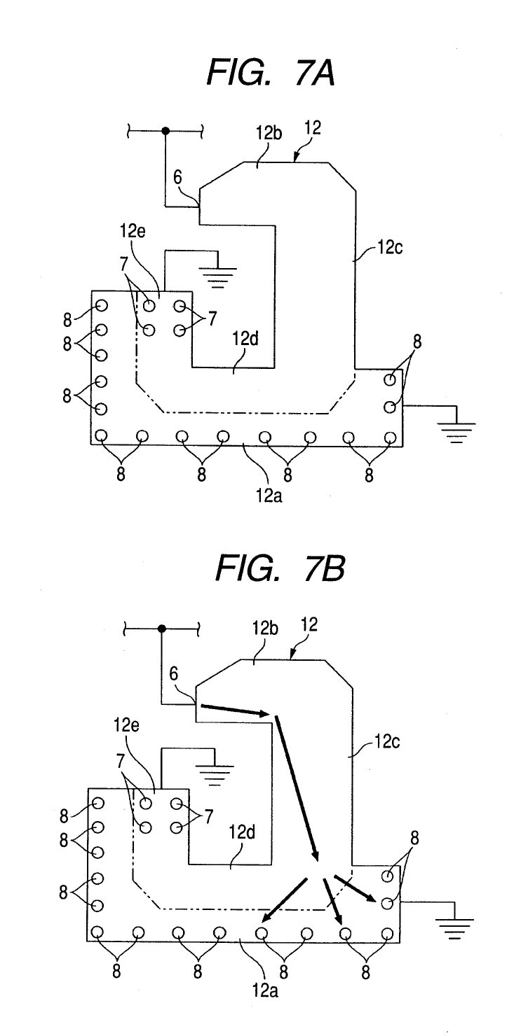

FIGS. 7A and 4B are plan views illustrating a configuration example of a microstrip line 12 applied to the voltage controlled oscillator 1 of the third embodiment. The voltage controlled oscillator 1 of the third embodiment also has the same circuit configuration as those of the first and second embodiments, except for the microstrip line 12 with a configuration different from those of the first and second embodiments. Hereinafter, the microstrip line 12 applied to the third embodiment will be described.

[Configuration Before Trimming]

Referring to FIG. 7A, similarly to the first and second embodiments, one end (the single input terminal 6) of the microstrip line 12 used for the third embodiment is also connected to the control terminal (not shown in FIG. 7A) and the other end of the microstrip line 12 is connected to the ground electrode on the circuit. The microstrip line 12 used for the third embodiment is provided at an outer peripheral portion (an outer side of a spiral) with a conductor 12a for coarse adjustment.

That is, the microstrip line 12 is provided at one end thereof with an input conductive portion 12b and at the other end thereof with a ground conductive portion 12e. Between them, the input conductive portion 12b is continuous to the signal input terminal 6, and the ground conductive portion 12e is connected to the ground electrode (not shown) through a plurality of vias 7. Further, two intermediate conductive portions 12c and 12d are arranged between the input conductive portion 12b and the ground conductive portion 12e. In this example, the one end of the microstrip line 12 is located at an outer side of the spiral and the other end thereof is located at a central side of the spiral.

The input conductive portion 12b is arranged approximately perpendicular to the first intermediate conductive portion 12c, and the first intermediate conductive portion 12c is arranged approximately perpendicular to the second intermediate conductive portion 12d. In addition, the second intermediate conductive portion 12d is arranged approximately perpendicular to the ground conductive portion 12e. These four conductive portions 12b to 12e are serially connected to one another while being sequentially arranged perpendicular to one another, so that the microstrip line 12 has a rectangular spiral shape as a whole.

Thus, in the microstrip line 12, the conductor 12a for coarse adjustment is located at an outer side of the spiral as described above. That is, the conductor 12a for coarse adjustment, for example, protrudes toward the outer side of the spiral from the vicinity of a connection point between the first intermediate conductive portion 12c and the second intermediate conductive portion 12d and extends to the second intermediate conductive portion 12d and an outer side of the ground conductive portion 12e continuous to the second intermediate conductive portion 12d. In addition, the conductor 12a for coarse adjustment is formed with a plurality of vias 8 along the outer peripheral portion thereof. In this example, the conductor 12a for coarse adjustment is connected to the ground electrode (not shown) through the plurality of vias 8.

[Line Length Before Trimming]

Referring to FIG. 7B, if a control voltage is input (applied) to the resonant circuit 2 in the state (before trimming) in which the conductor 12a for coarse adjustment remains on the substrate, as indicated by the arrow in FIG. 7B, the shortest range from the signal input terminal 6 to the via 8 of the outer peripheral portion by way of the input conductive portion 12b, the first intermediate conductive portion 12c, and the conductor 12a for coarse adjustment of the outer side from a starting end portion of the second intermediate conductive portion 12d becomes a conductive line as the microstrip line 12. In such a case, since the range from a part of a downstream, as compared with the starting end portion of the second intermediate conductive portion 12d when seen in the width direction, to the ground conductive portion 12e continuous to the second intermediate conductive portion 12d does not substantially contribute to conduction, the line length of the microstrip line 12 is reduced to that extent.

In the state in which the whole of the conductor 12a for coarse adjustment is maintained as described above, the inductance of the microstrip line 12 is determined after the line length of the microstrip line 12 is minimized. In the third embodiment, the resonant frequency (oscillation frequency of the voltage controlled oscillator 1) of the resonant circuit 2 at that time, for example, can be adjusted to a 2 GHz band.

### Trimming Example

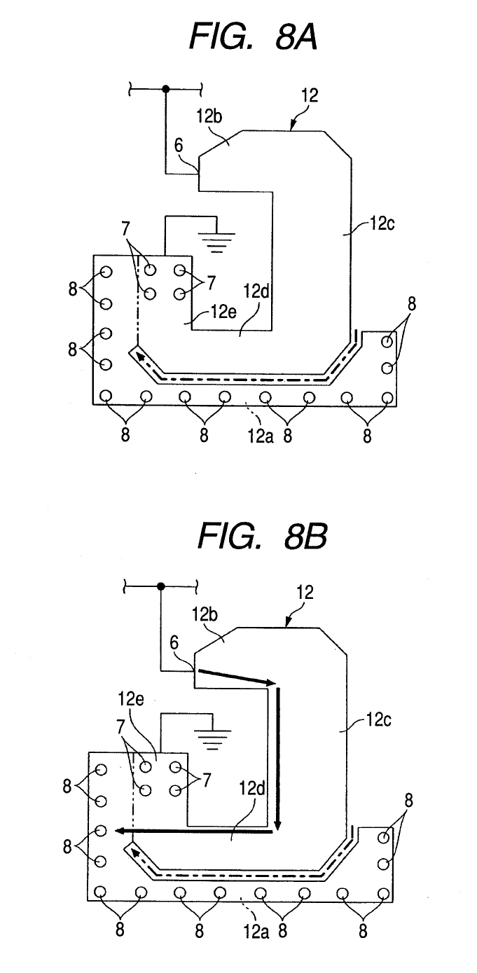

FIGS. 8A and 8B are diagrams illustrating an example of trimming the conductor 12a for coarse adjustment in the microstrip line 12.

Referring to FIG. 8A, the microstrip line 12 used for the third embodiment is suitable when the conductor 12a for coarse adjustment is continuously trimmed as described in the modification of the second embodiment. In detail, as indicated in an arrow of a dashed dotted line of FIG. 8A, the conductor 12a for coarse adjustment is continuously removed along the outer periphery of the second intermediate conductive portion 12d from the connection point between the two intermediate conductive portions 12c and 12d (i.e., the outer side of the starting end portion of the second intermediate conductive portion 12d), so that the line length of the microstrip line 12 as a whole can be continuously lengthened according to the length corresponding to the removed portion of the conductor 12a for coarse adjustment.

Further, in the example shown in FIG. 8A, it can be understood that the conductor 12a for coarse adjustment has been trimmed throughout the range from the starting end portion to the terminal end portion of the intermediate conductive portion 12d, that is, the range to the vicinity of the connection point between the intermediate conductive portion 12d and the ground conductive portion 12e. In such a case, in the range in which the conductor 12a for coarse adjustment has been removed by the trimming, the conductive line from the intermediate conductive portion 12d to the vias 8 of the conductor 12a for coarse adjustment is separated on the substrate.

[Line Length after Trimming]

Referring to FIG. 8B, thus, if a control voltage is input (applied) to the resonant circuit 2 after the trimming, as indicated by the arrow in FIG. 8B, the range from the signal input terminal 6 to the vias 8, which is located at the outer periphery of the conductor 12a for coarse adjustment, by way of the input conductive portion 12b, the first intermediate conductive portion 12c, the second intermediate conductive portion 12d, and the untrimmed portion of the conductor 12a for coarse adjustment becomes a conductive line as the microstrip line 12. In such a case, since the range including the whole of the first intermediate conductive portion 12c, the next intermediate conductive portion 12d, and the conductor 12a for coarse adjustment in front of the vias 8 contributes to the conduction, the line length of the microstrip line 12 is reduced to that extent as compared with the case in which the trimming is not performed.

In the state in which the conductor 12a for coarse adjustment has been partially removed as described above, since the line length of the microstrip line 12 extends according to the length of the trimmed range, the inductance is determined according to the line length after the extension. Consequently, in the third embodiment, the oscillation frequency band can be continuously adjusted according to the length of the range in which the conductor 12a for coarse adjustment is removed.

For example, when seen in the conduction direction from the signal input terminal 6, if it is assumed that the range up to the vias 8 located at the starting end portion of the conductor 12a for coarse adjustment serves as the shortest conductive line, the range up to the vias 8 located at the terminal end portion of the conductor 12a for coarse adjustment serves as the longest conductive line when seen in the conduction direction (here, vias 7 of the ground conductive portion 12e are excluded). Consequently, the trimming is continuously performed toward the terminal end from the starting end position of the conductor 12a for coarse adjustment, so that the line length in the microstrip line 12 extends according to the length corresponding to the trimmed portion, resulting in the continuous reduction of the oscillation frequency.

Further, even in the third embodiment, the line width in the microstrip line 12 is not narrowed before and after the trimming, so that deterioration of the Q factor due to the coarse adjustment can be prevented.

In addition, although not shown in FIGS. 8A and 8B, in the third embodiment, the trimming can be performed throughout the whole of the conductor 12a for coarse adjustment. In such a case, since both the intermediate conductive portion 12d and the ground conductive portion 12e are completely separated from the conductor 12a for coarse adjustment on the substrate, the range from the one end (the signal input terminal 6) of the microstrip line 12 to the vias 7 of the ground conductive portion 12e directly becomes the line length, so that the oscillation frequency can be adjusted (e.g., adjusted to a 1 GHz band) according to the length.

The present invention is not limited to the first to third embodiments as described above. That is, various modifications can be made. For example, the shapes of microstrip lines 10 to 12 are not limited to the examples shown in the drawings. That is, the microstrip lines 10 to 12 may have various shapes. Further, differently from the previous embodiments, the spiral may be formed in a reverse direction on the substrate, or the outer side and inner side of the spiral may be reversed.

Further, in the first embodiment, only one conductor 10a for coarse adjustment is formed. However, two or more conductors for coarse adjustment may be formed between the intermediate conductive portion 10c and the ground conductive portion 10e. In such a case, it is possible to perform the oscillation frequency band adjustment of three steps (high, intermediate and low) or more according to the number of conductors for coarse adjustment to be trimmed.

In addition, in the second embodiment, the conductors for coarse adjustment are divided into two conductors 11a and 11b. However, the conductors for coarse adjustment may be divided into three or more.

Moreover, the circuit configuration of the voltage controlled oscillator 1 shown in FIG. 1 is just one example. For example, it may be possible to form a circuit as an oscillator by adding other devices and circuit elements. Furthermore, FIG. 1 exemplifies the circuit structure of base input and collector ground. However, other input and ground schemes may be employed. For example, it may be possible to employ a circuit structure of collector input and base ground.

It should be understood by those skilled in the art that various modifications, combinations, sub-combinations and alterations may occur depending on design requirements and other factors insofar as they are within the scope of the appended claims or the equivalents thereof.

What is claimed is:

1. A voltage controlled oscillator with a microstrip line suitable for coarse adjustment of an oscillation frequency band, the voltage controlled oscillator comprising:
a transistor for oscillation that outputs an oscillation signal;
a microstrip line formed on a substrate together with the transistor for oscillation, having one end connected to the transistor for oscillation and the other end connected to a ground electrode formed on the substrate, and constituting a part of a frequency determining element that determines a frequency of the oscillation signal according to a line length from the one end of the microstrip line to the ground electrode; and
a conductor for coarse adjustment that connects between the one end and the other end of the microstrip line to the ground electrode, thereby reducing the line length of the microstrip line in the connection state.

2. The voltage controlled oscillator with a microstrip line suitable for coarse adjustment of an oscillation frequency band according to claim 1, wherein the conductor for coarse adjustment is provided in plural between the one end and the other end of the microstrip line to connect a plurality of places to the ground electrode, respectively.

3. The voltage controlled oscillator with a microstrip line suitable for coarse adjustment of an oscillation frequency band according to claim 1, wherein the microstrip line is formed in a spiral shape toward the other end from the one end thereof on the substrate, and the ground electrode is a ground terminal formed at the other end of the microstrip line.

4. The voltage controlled oscillator with a microstrip line suitable for coarse adjustment of an oscillation frequency band according to claim 1, wherein the microstrip line is formed in a spiral shape toward the other end from the one end thereof on the substrate, and the ground electrode is formed in an area along an outer periphery of the spiral from the other end of the microstrip line.

5. The voltage controlled oscillator with a microstrip line suitable for coarse adjustment of an oscillation frequency band according to claim 1, wherein the conductor for coarse adjustment has a length along a conduction direction of the microstrip line in an area, which connects between the one end and the other end of the microstrip line to the ground electrode when seen from the ground electrode, and extends the line length of the microstrip line according to reduction of a length caused by partial removal of the area.
